(19) United States
(12) Patent Application Publication
(10) Pub. No.: US 2016/0377991 A1
(43) Pub. Date: Dec. 29, 2016

(54) METHOD OF LAYER MANAGEMENT WITH DOUBLE-LAYER OVERLAY ACCURACY CONTROL, CALIBRATION MARK AND MEASUREMENT SYSTEM

(71) Applicants: Yiming Zhu, Shanghai (CN); Lijun Chen, Shanghai (CN); Peng Wu, Shanghai (CN); Jun Zhu, Shanghai (CN)

(72) Inventors: Yiming Zhu, Shanghai (CN); Lijun Chen, Shanghai (CN); Peng Wu, Shanghai (CN); Jun Zhu, Shanghai (CN)

(21) Appl. No.: 14/865,044

(22) Filed: Sep. 25, 2015

(30) Foreign Application Priority Data
Jun. 29, 2015 (CN) 201510369337.4

(51) Int. Cl. G03F 7/20

(52) U.S. Cl. CPC G03F 7/70633

(57) ABSTRACT

The present invention provides a method for solving the need for layer management with double-layer overlay accuracy control, a calibration mark structure which realizes the method and a measurement system with the calibration mark structure. The method modifies the layout of the overlay calibration marks such that overlay information of two layers is contained in one combined calibration mark, has realized the overlay accuracy data collection for the two previous layers in the current layer by one-time measurement, and can treat the overlay accuracies of the two layers as different control accuracies. Thus, the method can complete the automatic feedback optimization of the overlay accuracy compensation, is simple and easy, and can better help the enterprises for production quality assurance and cost control.

### CROSS-REFERENCE TO RELATED APPLICATION

This application claims the priority benefit of Chinese patent application serial No. 201510369337.4, filed on Jun. 29, 2015. The entirety of the above-mentioned patent application is hereby incorporated by reference herein and made a part of this specification.

### FIELD OF THE INVENTION

The present invention relates to the technical field of integrated circuit manufacturing and application, particularly to a method for solving the need for layer management with double-layer overlay accuracy control, a calibration mark structure which realizes the method and a measurement system.

### BACKGROUND OF THE INVENTION

With the unceasing development of the semiconductor manufacturing process and the continuous reduction of the line width size, the requirements for accuracy related to the lithography process and the lithography system are also increasing. Reflected on the overlay accuracy, the influence on the pass rate of the products is increasing. In brief, the so-called overlay accuracy is the alignment accuracy of the alignment marks of the current layer with respect to the marks of the previous layer in the lithography process. The lithography alignment, as one of the three cores of the lithography technology, generally requires the overly accuracy to be 1/7˜ 1/10 of the minimum line width size. For the technology node of 65 nm, the overlay accuracy is usually required to be at about 8 nm.

However, in the actual production run, due to various error factors and equipment differences, the overlay accuracy is difficult to be controlled steadily to be within the scope required by the lithography process. The process stability is thus affected severely. It has been found in the fabrication processing with processes of 55 nm and lower that some key processes need to simultaneously ensure the overlay accuracy of two layers.

At present, the practice in the prior art is to perform arrangement of two calibration marks (Overlay marks, which will be referred to as OVL marks hereinafter) on such layers, and to perform measurement of two sets of OVL data at the time of cargo delivery. For example, referring to FIG. 1, FIG. 1 is a schematic diagram of a calibration mark structure adopted in the method for solving the need for layer management with double-layer overlay accuracy control in the prior art. In the figure, reference signs 100, 200 and 300 are layer numbers. Provided that 100 is taken as the layer among the three layers that is completed first in the process, then, 200 is the layer that is fabricated secondly, and 300 is the layer that is completed last. In the processing of every layer, OVL Marks for the layer will be fabricated. As shown in the figure, from left to right, the OVL Marks fabricated at the time of the layer number 100 are presented in the first column, the OVL Marks fabricated at the time of the layer number 200 are presented in the second column, and the OVL Marks fabricated at the time of the layer number 300 are presented in the third column. It is apparent to those skilled in the art that the OVL Marks fabricated at the time of the lay number 100 are usually composed of two calibration marks 1001 and 1002. The calibration mark 1001 is used to measure the OVL Mark offset value of the layer number 200 with respect to the layer number 100. The calibration mark 1002 is used to measure the OVL Mark offset value of the layer number 300 with respect to the layer number 100. Each of the calibration marks is of four lines of the same length, which form one square. The OVL Marks fabricated at the time of the layer number 200 are usually composed of two calibration marks 2001 and 2002. Each of the calibration marks is of four lines of the same length, which form one square. The calibration mark 2001 overlays the calibration mark 1001 which is fabricated at the time of the layer number 100. The calibration mark 2002 is used to measure the OVL Mark offset value of the layer number 300 with respect to the layer number 100. The OVL Marks fabricated at the time of the layer number 300 are usually composed of two calibration marks 3001 and 3002. Each of the calibration marks is of four lines of the same length, which form one square. The calibration mark 3001 overlays the calibration mark 1002 which is fabricated at the time of the layer number 100. The calibration mark 3002 overlays the calibration mark (bar) 2002 which is fabricated at the time of the layer number 200.

In the measurement, it is necessary to test the OVL Mark offset value of the layer number 200 with respect to the layer number 100, the OVL Mark offset value of the layer number 300 with respect to the layer number 100 and the OVL Mark offset value of the layer number 300 with respect to the layer number 200, respectively. The error calibration in the prior art is completed by overlaying bar in bar the calibration mark of the previous layer, i.e., respectively consists of the measurement of two layers.

Referring to FIG. 2, FIG. 2 is a schematic diagram of the calibration offset position after measurement is performed on the calibration mark structure shown in FIG. 1 in the prior art. As shown in the figure, taking as an example the case where the calibration mark 2001 in the layer number 200 is translated in the X direction with respect to the calibration mark 1001 in the layer number 100, it can be seen that, when the calibration mark 2001 deviates in the negative X direction with respect to the calibration mark 1001, center deviation of the calibration mark of the previous layer will occur. This center deviation is related to the actual overlay offset of the layer number 200. Taking the calibration mark of the layer number 100 as a reference, since the relative position of translation in the X direction is the deviation of the two edges of a calibration mark, the calculation of the actual deviation amount is to measure and calculate distances between the two adjacent edges of the two calibration marks in the X direction, and then to calculate the value of half of the difference of the distance between the two adjacent edges, which can be taken as the actual deviation amount of the offset between the layer number 100 and the layer number 200.

In the actual operation, it can be preset to subtract the left interval from the right interval when the subtraction is performed on the two adjacent intervals of the two calibration marks in the X direction. Thus, if the actual deviation amount is negative, negative deviation occurs with respect to the ideal statuses of the center of the calibration mark 2001 in the layer number 200 and the center of the calibration mark 1001 in the layer number 100.

Similarly, the calculation of the actual deviation amount of the calibration mark 3001 in the layer 300 with respect to the calibration mark 1001 in the layer number 100, and the calculation of the actual deviation amount of the calibration mark 3002 in the layer number 300 with respect to the calibration mark 2002 in the layer number 200, are the same as that in the above-mentioned method, and will not be described redundantly herein.

However, the calibration mark of each point X/Y collected at the time of the lay number 300 are respectively composed of two layers. This will result in the center deviation of the calibration mark of the previous layer. This center deviation is related to the actual overlay offset of the layer number 200. Thus, in the calculation of the actual deviation amount of the calibration mark 3002 in the layer number 300 with respect to the calibration mark 2002 in the layer number 200, it is necessary to take into consideration the deviation result of the calibration mark 2001 in the layer number 200 with respect to the calibration mark 1001 in the layer number 100.

Therefore, the above-mentioned method in the prior art has consumed a lot of measurement resources. In addition, the calculation method of the overlay compensation value in the above-mentioned prior art can only be used in single-layer compensation. Consequently, it is impossible to perform compensation value feedback of two layers efficiently and properly, and there easily arises a problem of a high rework rate.

### BRIEF SUMMARY OF THE DISCLOSURE

In order to overcome the above problems, the present invention directs to provide a method for solving the need for layer management with double-layer overlay accuracy control, a calibration mark structure which realizes the method and a measurement system including the calibration mark structure. The method completes the overlay accuracy data collection for the two previous layers in the current layer by one-time measurement, and can treat the overlay accuracies of the two layers as different control accuracies. Thus, the method can complete the automatic feedback optimization of the overlay accuracy compensation, is simple and easy, and can better help the enterprises for production quality assurance and cost control.

To achieve the above object, the technical solution of the present invention is as follows: the present invention provides a method of layer management with double-layer overlay accuracy control, for calculating and controlling overlay accuracy involving calibration marks of three layers, the method comprises a calibration mark of three layers fabrication step S1 and a measurement step S2; the step S1 specifically comprises the following steps:

Step S11: fabricating a first layer calibration marking unit during performing a process of the first layer; that is, two sets of first calibration mark A1 are fabricated in different positions of the first fabricated layer, the first calibration mark A1 of the first set include four straight lines in the X and Y directions, which form a circle but have no intersection, and the first calibration mark A1 of the second set include two straight lines in the X and Y directions, which are adjacent to each other but have no intersection;

Step S12: fabricating a second layer calibration marking unit during performing a process of the second layer; that is, two sets of first calibration mark A1 and second calibration mark A2 are fabricated in different positions of the second fabricated layer; wherein the first calibration mark A1 are fabricated as in step S11, that is, the first calibration mark A1 of the first set include four straight lines in the X and Y directions, which form a circle but have no intersection, the first calibration mark A1 of the second set include two straight lines in the X and Y directions, which are adjacent to each other but have no intersection; the second calibration mark A2 of the first set include four straight lines in the X and Y directions, which form a circle but have no intersection, the second calibration mark A2 of the second set include two straight lines in the X and Y directions, which are adjacent to each other but have no intersection; the second calibration mark A2 of the first set is located within the first calibration mark A1 of the first set, and the second calibration mark A2 of the second set and the first calibration mark A1 of the second set are disposed in opposite positions, and form a circle to constitute a combined calibration mark;

Step S13: fabricating a third layer calibration marking unit during performing a process of the third layer; that is, two sets of first calibration mark A1, second calibration mark A2 and a third calibration mark A3 are fabricated in different positions of the third fabricated layer; wherein the first calibration mark A1 and the second calibration mark A2 are fabricated as in steps S11 and S12; the third calibration mark A3 include four straight lines in the X and Y directions, which form a circle but have no intersection, and are disposed within the combined calibration mark that is formed by the second calibration mark A2 of the second set and the first calibration mark A1 of the second set.

The step S2 specifically comprises the following steps:

Step S21: after the fabrication process of the second layer is completed, measuring intervals in the X and Y directions, of the second calibration mark A2 of the first set and the first calibration mark A1 of the first set, respectively, and calculating and obtaining a center offset value of the second layer with respect to the first layer, according to the obtained intervals;

Step S22: after the fabrication process of the third layer is completed, measuring intervals in the X and Y directions, of the second calibration mark A2 of the first set and the first calibration mark A1 of the first set, respectively, and calculating and obtaining a center offset value of the second layer with respect to the first layer according to the obtained intervals, and measuring intervals in the X and Y directions, of the third calibration mark A3 and the combined calibration mark which is formed by the first calibration mark A1 of the second set and the second calibration mark A2 of the second set, respectively, and calculating and obtaining center offset values in the X and Y directions of the second layer with respect to the first layer, of the third layer with respect to the first layer and of the third layer with respect to the second layer, according to the obtained intervals.

Preferably, after the step S2, the method further comprises:

Step S3: in double-layer overlay accuracy control, separate target value deviation setting and regulation are performed in accordance with actual placement statuses and specification requirements of the first calibration mark A1 of the two sets, the second calibration mark A2 of the two sets and the third calibration mark A3 of the one sets.

Preferably, the separate target value deviation setting and regulation in the step S3 are specifically: adding background operation, and correcting error of the combined calibration mark itself.

Preferably, in the combined calibration mark, the first calibration mark A1 are located in the upper left, and the second calibration mark A2 are located in the lower right.

Preferably, in the combined calibration mark, the first calibration mark A1 are located in the lower left, and the second calibration mark A2 are located in the upper right.

Preferably, in the combined calibration mark, the first calibration mark A1 are located in the lower right, and the second calibration mark A2 are located in the upper left.

Preferably, in the combined calibration mark, the first calibration mark A1 are located in the upper right, and the second calibration mark A2 are located in the lower left.

To achieve the above object, the present invention further provides a calibration mark structure for the method, that is used to calculate and control overlay accuracy involving calibration mark of three layers, which comprises a first layer calibration marking unit, a second layer calibration marking unit and a third layer calibration marking unit; the first layer calibration marking unit is fabricated during performing a process of the first layer; that is, two sets of first calibration mark A1 are fabricated in different positions of the first fabricated layer, the first calibration mark A1 of the first set include four straight lines in the X and Y directions, which form a circle but have no intersection, and the first calibration mark A1 of the second set include two straight lines in the X and Y directions, which are adjacent to each other but have no intersection; the second layer calibration marking unit is fabricated during performing a process of the second layer; that is, two sets of first calibration mark A1 and second calibration mark A2 are fabricated in different positions of the second fabricated layer; wherein the first calibration mark A1 are fabricated as in step S11, that is, the first calibration mark A1 of the first set include four straight lines in the X and Y directions, which form a circle but have no intersection, and the first calibration mark A1 of the second set include two straight lines in the X and Y directions, which are adjacent to each other but have no intersection; the second calibration mark A2 of the first set include four straight lines in the X and Y directions, which form a circle but have no intersection, and the second calibration mark A2 of the second set include two straight lines in the X and Y directions, which are adjacent to each other but have no intersection; the second calibration mark A2 of the first set is located within the first calibration mark A1 of the first set, and the second calibration mark A2 of the second set and the first calibration mark A1 of the second set are disposed in opposite positions, and form a circle to constitute a combined calibration mark; the third layer calibration marking unit is fabricated during performing a process of the third layer; that is, two sets of first calibration mark A1, second calibration mark A2 and one set of third calibration mark A3 are fabricated in different positions of the third fabricated layer; wherein the first calibration mark A1 and the second calibration mark A2 are fabricated as in steps S11 and S12; the third calibration mark A3 include four straight lines in the X and Y directions, which form a circle but have no intersection, and are disposed within the combined calibration mark that is formed by the second calibration mark A2 of the second set and the first calibration mark A1 of the second set. To achieve the above object, the present invention further provides a measurement system including the calibration mark structure, which further comprises a control unit that performs separate target value deviation setting and regulation in accordance with actual placement statuses and specification requirements of the first calibration mark A1, the second calibration mark A2 and the third calibration mark A3 of the two sets, the regulation being adding background operation, and correcting error of the combined calibration mark itself.

It can be seen from the above-mentioned technical solutions that the present invention can complete the overlay accuracy data collection for two layers, by one-time measurement and feedback using the measurement value directly, thus realizing the calculation and feedback of the compensation value at the time of the overlay control for the two layers, and reducing the rework rate. When separate regulation needs to be performed in the middle of the calibration marks of two layers in the case where there is no center offset by default, the target value deviation setting is performed in accordance with the actual placement status and the specification requirement of each calibration mark. By the target value deviation control method, the separate management and control of the overlay data of the two layers, and the operation of the automatic compensation feedback mechanism are realized.

### BRIEF DESCRIPTION OF THE DRAWINGS

FIG. 1 is a schematic diagram of a calibration mark structure adopted in a method for solving the need for layer management with double-layer overlay accuracy control in the prior art

FIG. 2 is a schematic diagram of the calibration offset position after measurement is performed on the calibration mark structure shown in FIG. 1 in the prior art

FIG. 3 is a schematic diagram of a calibration mark structure adopted in the method for solving the need for layer management with double-layer overlay accuracy control in an embodiment of the present invention

FIG. 4 is a schematic diagram of the offset position after measurement is performed on the calibration mark structure shown in FIG. 3 in the embodiment of the present invention

FIG. 5 is a schematic diagram of four types of calibration mark structures in an embodiment of the present invention.

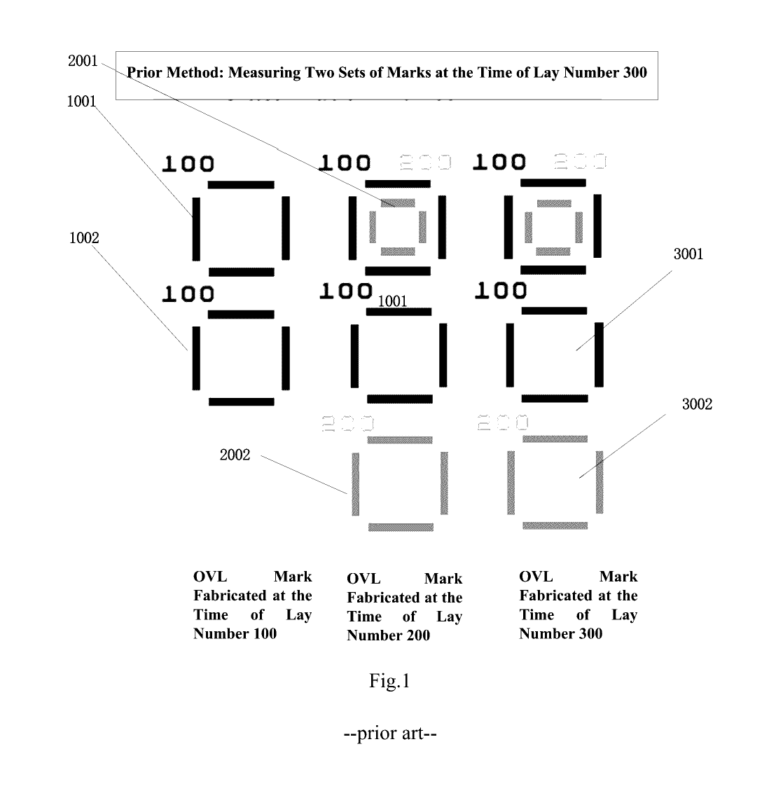

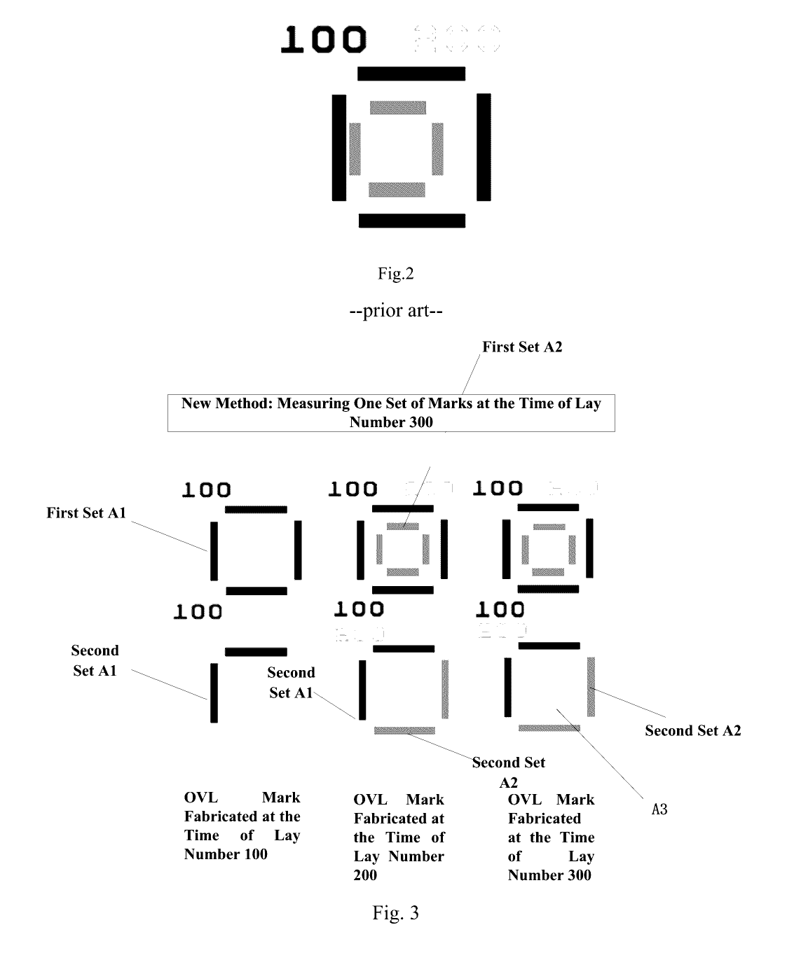

### DETAILED DESCRIPTION OF THE EMBODIMENTS

The present invention will be described in further details hereinafter by referring to the accompanying drawings, so as to provide a better understanding of the present invention. However, the present invention is not limited to these embodiments. All equivalent modifications and substitutions without departing from the spirit and scope of the present invention should be covered by the present invention.

Hereinafter, a method for solving the need for layer management with double-layer overlay accuracy control, a calibration mark structure which realizes the method and a measurement system will be described in detailed by specific embodiments with reference to FIGS. 3-5. It should be noted that the drawings all adopt a much simplified form, use a proportion not precise, and are only used for the purpose of assisting in describing the embodiments of the present invention conveniently and clearly.

In the embodiments of the present invention, by introducing the concept of combined calibration mark, the combined calibration mark overlays bar in bar the calibration marks of the previous layer, the arrangement of one calibration mark (Overlay mark, which will be referred to as OVL mark hereinafter) is performed on one such layers, and the measurement of two sets of OVL data is performed on one layer at the time of cargo delivery.

Referring to FIG. 3, FIG. 3 is a schematic diagram of a calibration mark structure adopted in a method for solving the need for layer management with double-layer overlay accuracy control in an embodiment of the present invention. In the figure, reference signs 100, 200 and 300 are layer numbers. Provided that 100 is taken as the layer among the three layers that is completed first in the process, then, 200 is the layer that is fabricated secondly, and 300 is the layer that is completed last. In the processing of every layer, the OVL Marks for the layer will be fabricated. As shown in the figure, the calibration mark structure in the embodiment of the present invention which is used to calculate and control the overlay accuracy involving the calibration marks of three layers, includes a first layer calibration marking unit, a second layer calibration marking unit and a third layer calibration marking unit.

Specifically, as shown in the figure, from left to right, the OVL Marks (a first layer calibration marking unit) fabricated at the time of the layer number 100 are presented in the first column, the OVL Marks (a second layer calibration marking unit) fabricated at the time of the layer number 200 are presented in the second column, and the OVL Marks (a third layer calibration marking unit) fabricated at the time of the layer number 300 are presented in the third column.

The fabrication of the first layer calibration marking unit is completed during performing the process of the first layer. That is, two sets of first calibration mark A1 are fabricated in different positions of the first fabricated layer. The first calibration mark A1 of the first set include four straight lines in the X and Y directions, which form a circle but have no intersection. The first calibration mark A1 of the second set include two straight lines in the X and Y directions, which are adjacent to each other but have no intersection.

The fabrication of the second layer calibration marking unit is completed during performing the process of the second layer. That is, two sets of first calibration mark A1 and second calibration mark A2 are fabricated in different positions of the second fabricated layer. Wherein, the first calibration mark A1 are fabricated as in step S11. That is, the first calibration mark A1 of the first set include four straight lines in the X and Y directions, which form a circle but have no intersection. The first calibration mark A1 of the second set include two straight lines in the X and Y directions, which are adjacent to each other but have no intersection. The second calibration mark A2 of the first set include four straight lines in the X and Y directions, which form a circle but have no intersection. The second calibration mark A2 of the second set include two straight lines in the X and Y directions, which are adjacent to each other but have no intersection. The second calibration mark A2 of the first set is located within the first calibration mark A1 of the first set. The second calibration mark A2 of the second set and the first calibration mark A1 of the second set are disposed in opposite positions, and form a circle to constitute a combined calibration mark.

The fabrication of the third layer calibration marking unit is completed during performing the process of the third layer. That is, two sets of the first calibration mark A1, two sets of the second calibration mark A2 and one set of third calibration mark A3 are fabricated in different positions of the third fabricated layer. Wherein, the first calibration mark A1 and the second calibration mark A2 are fabricated as in steps S11 and S12. The third calibration mark A3 include four straight lines in the X and Y directions, which form a circle but have no intersection, and are disposed within a combined calibration mark that is formed by the second calibration mark A2 of the second set and the first calibration mark A1 of the first second set.

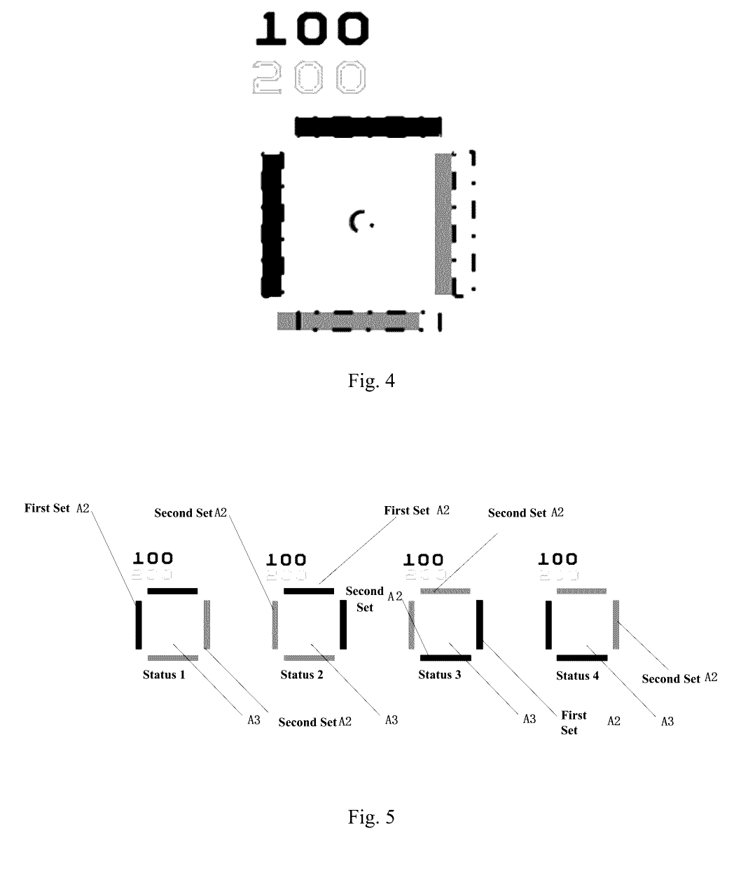

Referring to FIG. 4, FIG. 4 is a schematic diagram of the offset position after measurement is performed on the calibration mark structure shown in FIG. 3 in the embodiment of the present invention. As shown in the figure, in the first type of combined calibration mark, the first calibration mark A1 can be located in the upper left, and the second calibration mark A2 can be located in the lower right. In the second type of combined calibration mark, the first calibration mark A1 can be located in the lower left, and the second calibration mark A2 can be located in the upper right. In the third type of combined calibration mark, the first calibration mark A1 can be located in the lower right, and the second calibration mark A2 can be located in the upper left. In the fourth type of combined calibration mark, the first calibration mark A1 can be located in the upper right, and the second calibration mark A2 can be located in the lower left.

In the measurement, the OVL Mark offset value of the layer 200 with respect to the layer number 100 can be tested first by the structure formed by the second calibration mark A2 of the first set being located within the first calibration mark A1 of the first set. Then, by the structure of the third calibration mark A3 being disposed within the combined calibration mark, the OVL Mark offset value of the layer number 300 with respect to the layer number 100 and the OVL Mark offset value of the layer number 300 with respect to the layer number 200 are tested directly. That is, the error calibration thereof is completed by overlaying bar in bar the OVL marks of the previous layer. Namely, the desired measurement result can be achieved in the current layer.

Referring to FIG. 5, FIG. 5 is a schematic diagram of four types of calibration mark structures in an embodiment of the present invention. As shown in the figure, taking as an example the case where the layer number 200 is translated in the X direction with respect to the layer number 100 (the broken line is the status of mark in the ideal situation, and the solid line is the actual status), it can be seen that, when the layer number 200 deviates in the negative X direction with respect to the layer number 100, the negative deviation occurs with respect to the ideal statuses of the center of the combined calibration mark and the layer number 100. The offset of the previous layer number 200 with respect to the layer number 100 leads to the center position offset after the combination of double-layer calibration offsets.

As shown in the figure, in the embodiment of the present invention, in the X or Y direction, the combined calibration mark has only the edge on one side. Taking the X direction as an example, only the mark offset of one edge in the X direction is taken into consideration. Thus, the center position deviation amount is also ½ of the value of the layer number 200 with respect to the layer number 100.

The calculation method of center position deviation amount of the four statuses in FIG. 4 is: to set two axes of X/Y with the original calibration mark center of the first layer as the origin. In the obtaining of the data of the layer 200, ½ of the data of the corresponding point of the layer 200 with respect to the layer number 100 is subtracted when the calibration mark center of the layer 200 is on the positive axis, and similarly is added when on the negative axis. In the obtaining of the data of the layer number 100, the data of the corresponding point of the layer number 200 with respect to the layer 100 is added when the calibration mark of the layer number 100 are on the positive axis, and similarly is subtracted when on the negative axis.

Base on the above-mentioned calibration mark structure, in the embodiment of the present invention, there is provided a method of layer management with double-layer overlay accuracy control, for calculating and controlling overlay accuracy involving calibration mark of three layers, the method comprises a calibration mark of three layers fabrication step S1 and a measurement step S2; the step S1 specifically comprises the following steps:

step S11: fabricating a first layer calibration marking unit during performing a process of the first layer; that is, two sets of first calibration mark A1 are fabricated in different positions of the first fabricated layer, the first calibration mark A1 of the first set include four straight lines in the X and Y directions, which form a circle but have no intersection, and the first calibration mark A1 of the second set include two straight lines in the X and Y directions, which are adjacent to each other but have no intersection;

step S12: fabricating a second layer calibration marking unit during performing a processing procedure of the second layer; that is, two sets of first calibration mark A1 and second calibration mark A2 are fabricated in different positions of the second fabricated layer; wherein the first calibration mark A1 are fabricated as in step S11, that is, the first calibration mark A1 of the first set include four straight lines in the X and Y directions, which form a circle but have no intersection, and the first calibration mark A1 of the second set include two straight lines in the X and Y directions, which are adjacent to each other but have no intersection; the second calibration mark A2 of the first set include four straight lines in the X and Y directions, which form a circle but have no intersection, and the second calibration mark A2 of the second set include two straight lines in the X and Y directions, which are adjacent to each other but have no intersection; the second calibration mark A2 of the first set is located within the first calibration mark A1 of the first set, and the second calibration mark A2 of the second set and the first calibration mark A1 of the second set are disposed in opposite positions, and form a circle to constitute a combined calibration mark;

step S13: fabricating a third layer calibration marking unit during performing a process of the third layer; that is, two sets of first calibration mark A1, second calibration mark A2 and third calibration mark A3 are fabricated in different positions of the third fabricated layer; wherein the first calibration mark A1 and the second calibration mark A2 are fabricated as in steps S11 and S12; the third calibration mark A3 include four straight lines in the X and Y directions, which form a circle but have no intersection, and are disposed within a combined calibration mark that is formed by the second calibration mark A2 of the second set and the first calibration mark A1 of the second set.

The step S2 specifically comprises the following steps:

step S21: after the fabrication process of the second layer is completed, measuring intervals in the X and Y directions, of the second calibration mark A2 of the first set and the first calibration mark A1 of the first set, respectively, and calculating and obtaining a center offset value of the second layer with respect to the first layer, according to the obtained intervals;

step S22: after the fabrication process of the third layer is completed, measuring intervals in the X and Y directions, of the second calibration mark A2 of the first set and the first calibration mark A1 of the first set, respectively, and calculating and obtaining a center offset value of the second layer with respect to the first layer according to the obtained intervals, and measuring intervals in the X and Y directions, of the third calibration mark A3 and a combined calibration mark that is formed by the first calibration mark A1 of the second set and the second calibration mark A2 of the second set, respectively, and calculating and obtaining center offset values of the second layer with respect to the first layer, of the third layer with respect to the first layer and of the third layer with respect to the second layer, according to the obtained intervals.

Since the measurement in the embodiment of the present invention is to perform one-time measurement on one layer, it is possible to perform feedback using the measurement value directly. If separate regulation needs to be performed in the middle of the calibration mark of two layers in the case where there is no offset by default, the target value deviation setting can be performed in accordance with the actual placement statuses and the specification requirements of the calibration mark.

Specifically, after the step S2, the method further comprises:

step S3: in double-layer overlay accuracy control, separate target value deviation setting and regulation are performed in accordance with actual placement statuses and specification requirements of the first calibration mark A1, the second calibration mark A2 and the third calibration mark A3 of the two sets. The separate target value deviation setting and regulation in the step S3 specifically comprises: adding background operation and correcting error of the combined calibration mark itself.

In addition, in the embodiment of the present invention, there is further provided a measurement system including the calibration mark structure, which further comprises a control unit that performs separate target value deviation setting and regulation in accordance with actual placement statuses and specification requirements of the first calibration mark A1 of the two sets, the second calibration mark A2 of the two sets and the third calibration mark A3 of the one set, the regulation comprising adding background operation, and correcting error of the combined calibration mark itself.

In summary, the present invention can complete the overlay accuracy data collection of two layers, by one-time measurement and feedback using the measurement value directly, thus realizing the calculation and feedback of the compensation value at the time of the overlay control of the two layers, and reducing the rework rate; which is specifically manifested by:

1) modifying the layout of the overlay calibration mark such that overlay information of two layers is contained in one combined calibration mark, which meets the requirement for collecting the overlay accuracy data of the two layers by one-time measurement of layer in the subsequent process;

2) adding the background operation, and correcting the error of the combined calibration mark of the two layers itself;

3) by the target value deviation control method, realizing the separate management and control of the overlay data of the two layers, and the operation of the automatic compensation feedback mechanism.

While the invention has been described in connection with preferred embodiments, it will be understood that modifications thereof within the principles outlined above will be evident to those skilled in the art, and thus the invention is not limited to the preferred embodiments but is intended to encompass such modifications. The invention resides in each and every novel characteristic feature and each and every combination of characteristic features. Reference numerals in the claims do not limit their protective scope.

1. A method of layer management with double-layer overlay accuracy control, for calculating and controlling overlay accuracy involving calibration marks of three layers, wherein comprising a calibration mark structure fabrication step S1 and an overlay accuracy error measurement step S2;
the step S1 specifically comprises the following steps:
step S11: fabricating a first layer calibration marking unit during performing a process of the first layer; that is, two sets of first calibration mark (A1) are fabricated in different positions of the first fabricated layer, the first calibration mark (A1) of the first set include four straight lines in the X and Y directions, which form a circle but have no intersection, and the first calibration mark (A1) of the second set include two straight lines in the X and Y directions, which are adjacent to each other but have no intersection;
step S12: fabricating a second layer calibration marking unit during performing a process of the second layer; that is, two sets of first calibration mark (A1) and second calibration mark (A2) are fabricated in different positions of the second fabricated layer; wherein the first calibration mark (A1) are fabricated as in step S11, that is, the first calibration mark (A1) of the first set include four straight lines in the X and Y directions, which form a circle but have no intersection, the first calibration mark (A1) of the second set include two straight lines in the X and Y directions, which are adjacent to each other but have no intersection; the second calibration mark (A2) of the first set include four straight lines in the X and Y directions, which form a circle but have no intersection, the second calibration mark (A2) of the second set include two straight lines in the X and Y directions, which are adjacent to each other but have no intersection; the second calibration mark (A2) of the first set is located within the first calibration mark (A1) of the first set, and the second calibration mark (A2) of the second set and the first calibration mark (A1) of the second set are disposed in opposite positions, and form a circle to constitute a combined calibration mark;
step S13: fabricating a third layer calibration marking unit during performing a process of the third layer; that is, two sets of first calibration mark (A1), second calibration mark (A2) and third calibration mark (A3) are fabricated in different positions of the third fabricated layer; wherein the first calibration mark (A1) and the second calibration mark (A2) are fabricated as in steps S11 and S12; the third calibration mark (A3) include four straight lines in the X and Y directions, which form a circle but have no intersection, and are disposed within a combined calibration mark that is formed by the second calibration mark (A2) of the second set and the first calibration mark (A1) of the second set;
the step S2 specifically comprises the following steps:
step S21: after the fabrication process of the second layer is completed, measuring intervals in the X and Y directions, of the second calibration mark (A2) of the first set and the first calibration mark (A1) of the first set, respectively, and calculating and obtaining a center offset value of the second layer with respect to the first layer by calculation, according to the obtained intervals;
step S22: after the fabrication process of the third layer is completed, measuring intervals in the X and Y directions, of the second calibration mark(A2) of the first set and the first calibration mark (A1) of the first set, respectively, and calculating and obtaining a center offset value of the second layer with respect to the first layer according to the obtained intervals, and measuring intervals in the X and Y directions, of the third calibration mark (A3) and the combined calibration mark, respectively, and calculating and obtaining center offset values in the X and Y directions of the second layer with respect to the first layer, of the third layer with respect to the first layer and of the third layer with respect to the second layer, according to the obtained intervals.

2. The method according to claim 1, wherein, after the step S2 is performed, the method further comprises:
step S3: in performing double-layer overlay accuracy control, separate target value deviation setting and regulation are performed in accordance with actual placement statuses and specification requirements of the first calibration mark (A1) of the two sets, the second calibration mark (A2) of the two sets and the third calibration mark (A3) of the one set.

3. The method according to claim 2, wherein, the separate target value deviation setting and regulation in the step S3 specifically comprise the following steps:
adding background operation and correcting error of the combined calibration mark itself.

4. (canceled)

5. (canceled)

6. (canceled)

7. (canceled)

8. A calibration mark structure for realizing the method according to claim 1, that is used to calculate and control overlay accuracy involving calibration mark of three layers, wherein comprising:
a first layer calibration marking unit which is fabricated during performing a process of the first layer; that is, two sets of first calibration mark (A1) are fabricated in different positions of the first fabricated layer, the first calibration mark (A1) of the first set include four straight lines in the X and Y directions, which form a circle but have no intersection, and the first calibration mark (A1) of the second set include two straight lines in the X and Y directions, which are adjacent to each other but have no intersection;
a second layer calibration marking unit which is fabricated during performing a process of the second layer; that is, two sets of first calibration mark (A1) and second calibration mark (A2) are fabricated in different positions of the second fabricated layer; wherein the first calibration mark (A1) are fabricated as in step S11, that is, the first calibration mark (A1) of the first set include four straight lines in the X and Y directions, which form a circle but have no intersection, the first calibration mark (A1) of the second set include two straight lines in the X and Y directions, which are adjacent to each other but have no intersection; the second calibration mark (A2) of the first set include four straight lines in the X and Y directions, which form a circle but have no intersection, the second calibration mark (A2) of the second set include two straight lines in the X and Y directions, which are adjacent to each other but have no intersection; the second calibration mark (A2) of the first set is located within the first calibration mark (A1) of the first set, and the second calibration mark (A2) of the second set and the first calibration mark (A1) of the second set are disposed in opposite positions, and form a circle to constitute a combined calibration mark;
a third layer calibration marking unit which is fabricated during performing a process of the third layer; that is, two sets of first calibration mark (A1), second calibration mark (A2) and third calibration mark (A3) are fabricated in different positions of the third fabricated layer; wherein the first calibration mark (A1) and the second calibration mark (A2) are fabricated as in steps S11 and S12; the third calibration mark (A3) include four straight lines in the X and Y directions, which form a circle but have no intersection, and are disposed within a combined calibration mark that is formed by the second calibration mark (A2) of the second set and the first calibration mark (A1) of the second set.

9. The calibration mark structure according to claim 8, wherein, in the combined calibration mark, the first calibration mark (A1) are located in the upper left, and the second calibration mark (A2) are located in the lower right.

10. The calibration mark structure according to claim 8, wherein, in the combined calibration mark, the first calibration mark (A1) are located in the lower left, and the second calibration mark (A2) are located in the upper right.

11. The calibration mark structure according to claim 8, wherein, in the combined calibration mark, the first calibration mark (A1) are located in the lower right, and the second calibration mark (A2) are located in the upper left.

12. The calibration mark structure according to claim 8, wherein, in the combined calibration mark, the first calibration mark (A1) are located in the upper right, and the second calibration mark (A2) are located in the lower left.

13. A measurement system including the calibration mark structure according to claim 8, wherein, further comprising a control unit which performs separate target value deviation setting and regulation in accordance with actual placement statuses and specification requirements of the first calibration mark (A1), the second calibration mark (A2) and the third calibration mark (A3) of the two sets, the regulation is to add background operation and correct error of the combined calibration mark itself.

14. The method according to claim 1, wherein, in the combined calibration mark, the first calibration mark (A1) and the second calibration mark (A2) are located in two diagonally opposed vertices; that is, when the first calibration mark (A1) is located in the upper left, then the second calibration mark (A2) is located in lower right; when the first calibration mark (A1) is located in the lower left, then the second calibration mark (A2) is located in upper right; when the first calibration mark (A1) is located in the lower right, then the second calibration mark (A2) is located in upper left; when the first calibration mark (A1) is located in the upper right, then the second calibration mark (A2) is located in lower left.

15. The method according to claim 2, wherein, in the combined calibration mark, the first calibration mark (A1) and the second calibration mark (A2) are located in two diagonally opposed vertices; that is, when the first calibration mark (A1) is located in the upper left, then the second calibration mark (A2) is located in lower right; when the first calibration mark (A1) is located in the lower left, then the second calibration mark (A2) is located in upper right; when the first calibration mark (A1) is located in the lower right, then the second calibration mark (A2) is located in upper left; when the first calibration mark (A1) is located in the upper right, then the second calibration mark (A2) is located in lower left.

16. The method according to claim 3, wherein, in the combined calibration mark, the first calibration mark (A1) and the second calibration mark (A2) are located in two diagonally opposed vertices; that is, when the first calibration mark (A1) is located in the upper left, then the second calibration mark (A2) is located in lower right; when the first calibration mark (A1) is located in the lower left, then the second calibration mark (A2) is located in upper right; when the first calibration mark (A1) is located in the lower right, then the second calibration mark (A2) is located in upper left; when the first calibration mark (A1) is located in the upper right, then the second calibration mark (A2) is located in lower left.
